(19) United States
(12) Patent Application Publication
(10) Pub. No.: US 2012/0153385 A1
(43) Pub. Date: Jun. 21, 2012

(54) SEMICONDUCTOR DEVICE AND METHOD FOR FABRICATING THE SAME

(76) Inventor: Dae-Young SEO, Gyeonggi-do (KR)

(21) Appl. No.: 13/231,495

(22) Filed: Sep. 13, 2011

(30) Foreign Application Priority Data
Dec. 17, 2010 (KR) 10-2010-0130104

(51) Int. Cl. H01L 29/78; H01L 21/336

(52) U.S. Cl. 257/334; 438/270; 257/E21.41; 257/E29.262

(57) ABSTRACT

A semiconductor device that secures a contact margin between a storage node contact plug and an active region and a method for fabricating the same. A method for fabricating a semiconductor device includes forming a device isolation layer defining active regions extending in a first direction a substrate, forming a first trench extending across the active regions and the device isolation layer by selectively etching the substrate, forming a second trench under the first trench to isolate the active regions which are adjacent in the first direction by selectively etching the substrate, and forming a gate electrode filling the first and second trenches.

### CROSS-REFERENCE TO RELATED APPLICATIONS

The present application claims priority of Korean Patent Application No. 10-2010-0130104, filed on Dec. 17, 2010, which is incorporated herein by reference in its entirety.

### BACKGROUND

1. Field

Exemplary embodiments of the present invention relate to semiconductor device fabrication technology, and more particularly, to a semiconductor device based on self-alignment isolation and a method for fabricating the same.

2. Description of the Related Art

With the development of semiconductor device fabrication technology, the size of semiconductor devices decreases and the integration density thereof increases rapidly. In a semiconductor memory device such as a dynamic random access memory (DRAM), a cell structure is changing from an 8 F² cell structure to a 6 F² cell structure with the acceleration to the high integration. Here, F denotes a critical dimension (feature size) applied to a design rule.

FIGS. 1A to 1C, FIGS. 2A to 2C, and FIGS. 3A to 3C are views illustrating a conventional semiconductor device. FIGS. 1A to 1C are plan views of the conventional semiconductor device. FIGS. 2A to 2C are cross-sectional views of the conventional semiconductor device taken along a line I-I′ of FIGS. 1A to 1C, respectively. FIGS. 3A to 3C are cross-sectional views of the conventional semiconductor device taken along a line II-II′ of FIGS. 1A to 1C, respectively. FIGS. 4A and 413 are pictures illustrating the features of the conventional semiconductor device.

Referring to FIGS. 1A, 2A and 3A, a line-type hard mask pattern 12 extending in an oblique direction is formed on a substrate 11.

Referring to FIGS. 1B, 2B and 3B, an isolation cut mask 101 is used to selectively etch the hard mask pattern 12. Hereinafter, the island-type hard mask pattern formed by selectively etching the hard mask pattern 12 by using the isolation cut mask 101 will be denoted by ‘12A’.

Using the hard mask pattern 12A as an etch barrier, the substrate 11 is etched to form a trench for device isolation. The trench is filled with a dielectric material to form a device isolation layer 13, thereby defining an island-type active region 14 having a major axis and a minor axis.

Referring to FIGS. 1C, 2C and 3C, the hard mask pattern 12A, the device isolation layer 13, and the substrate 11 of the active region 14 are selectively etched to form a line-type trench 15 that crosses the active region 14 and the device isolation layer 13. Hereinafter, the hard mask pattern formed by selectively etching the hard mask pattern 12A to form the trench 15 will be denoted by ‘12B’.

A gate dielectric (not illustrated) is formed on the trench 15. A gate electrode 16 filling a portion of the trench 15 and a sealing layer 17 filling the other portion of the trench 15 are sequentially formed to complete a buried gate.

However, the conventional technology may degrade the reliability and characteristics of the semiconductor device because it forms the line-type hard mask pattern 12, forms the island-type hard mask pattern 12A by using the isolation cut mask, and forms the active region 14 by using the island-type hard mask pattern 12A.

Specifically, the island-type hard mask pattern 12A may easily lean in the conventional semiconductor device (refer to FIG. 4A). Also, ⁻15 because the size and position of the active region 14 in the major-axis direction are predefined by the island-type hard mask pattern 12A formed using the isolation cut mask, the alignment margin may be reduced in the buried gate forming process and the active region 14 may be formed in a shorter length than a predetermined length in the major-axis direction, thus reducing the contact margin between the active region 14 and a storage node contact plug (SNC) to be formed through the subsequent process (refer to ‘A’ of FIG. 4B).

### SUMMARY

An embodiment of the present invention is directed to a semiconductor device capable of preventing a hard mask pattern defining an active region from leaning, and a method for fabricating the same.

Another embodiment of the present invention is directed to a semiconductor device capable of securing a contact margin between a storage node contact plug and an active region, and a method for fabricating the same.

In accordance with an embodiment of the present invention, a iii semiconductor device includes: a device isolation layer disposed in a substrate to define active regions extending in a first direction; a first trench disposed in the substrate to cross the active regions and the device isolation layer; a second trench disposed under the first trench to isolate the active regions which are adjacent in first direction; and is a gate electrode disposed in the first and second trenches.

In accordance with another embodiment of the present invention, a method for fabricating a semiconductor device includes: forming a device isolation layer defining active regions extending in a first direction in a substrate; forming a first trench extending across the active regions and the device isolation layer by selectively etching the substrate; forming a second trench under the first trench to isolate the active regions which are adjacent in the first direction by selectively etching the substrate; and forming a gate electrode filling the first and second trenches.

### BRIEF DESCRIPTION OF THE DRAWINGS

FIGS. 1A to 1C are plan views of a conventional semiconductor device.

FIGS. 2A to 2C are cross-sectional views of the conventional semiconductor device taken along a line I-I′ of FIGS. 1A to 1C.

FIGS. 3A to 3C are cross-sectional views of the conventional semiconductor device taken along a line II-II′ of FIGS. 1A to 1C.

FIGS. 4A and 4B are pictures illustrating the features of the conventional semiconductor device.

FIGS. 5A to 5D are views illustrating a semiconductor device in accordance with an embodiment of the present invention.

FIGS. 6A to 6F are plan views illustrating a method for fabricating a semiconductor device in accordance with an embodiment of the present invention.

FIGS. 7A to 7F are cross-sectional views taken along a line I-I′ of FIGS. 6A to 6F.

FIGS. 8A to 8F are cross-sectional views taken along a line II-II′ of FIGS. 6A to 6F.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to dearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The present invention provides a semiconductor device, which can prevent a hard mask pattern defining an active region from leaning in a semiconductor device with a 6 F² cell structure and can secure a contact margin between a storage node contact plug and an active region, and a method for fabricating the same. To this end, the present invention forms an active region and a device isolation layer in the shape of a line-type pattern extending in one direction, and uses self-alignment isolation method to isolate the active regions which are adjacent to each other in the one direction (e.g., the major-axis direction).

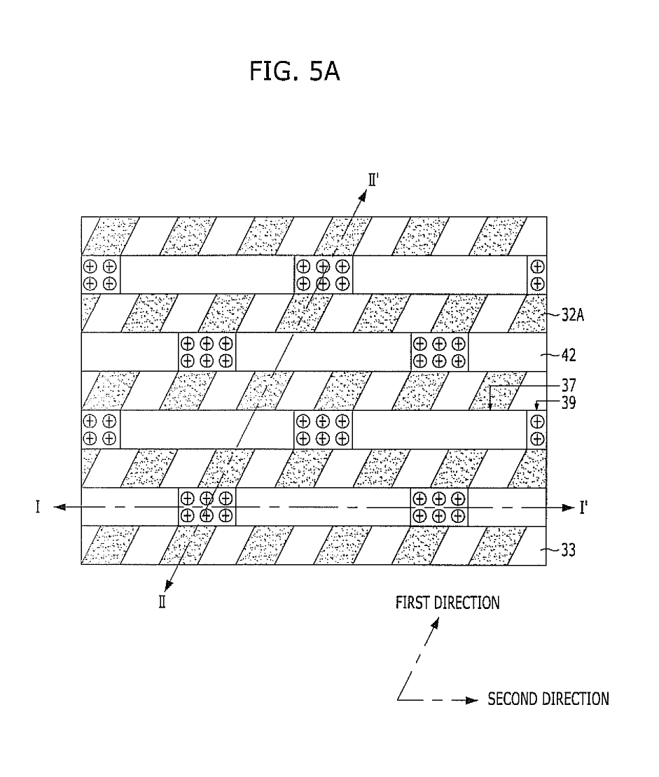

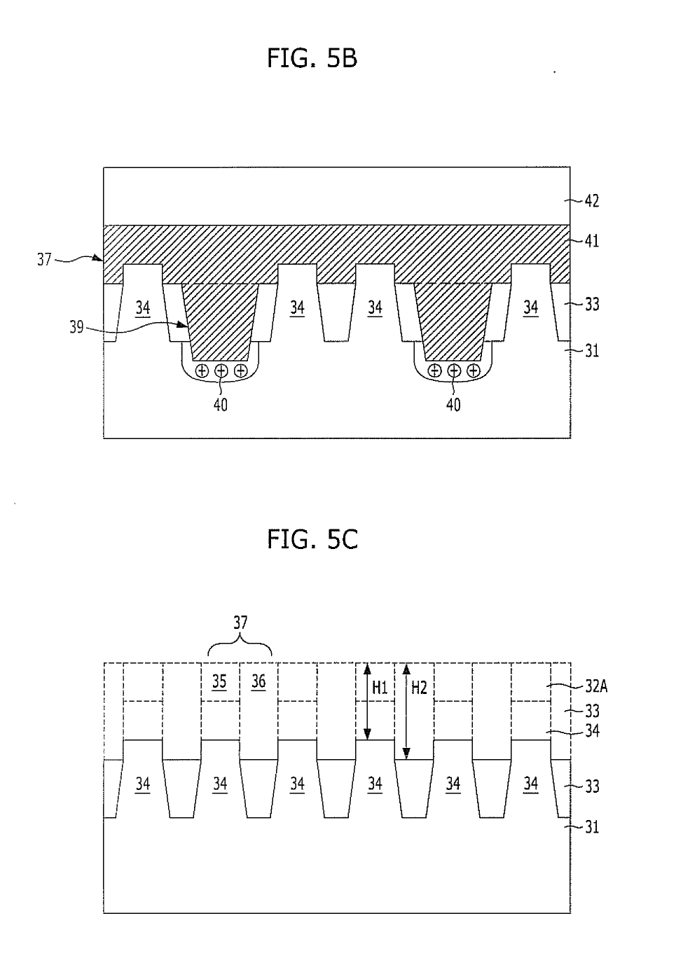

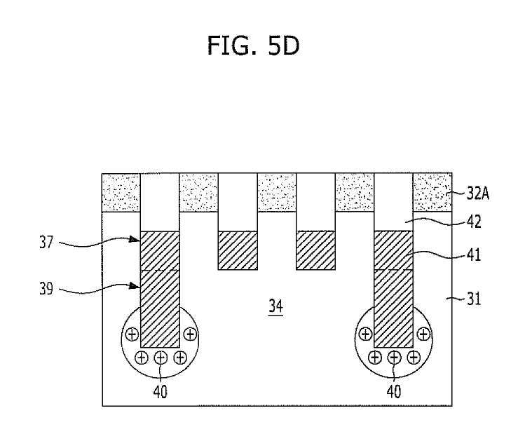

FIGS. 5A to 5D are views illustrating a semiconductor device in accordance with an embodiment of the present invention. FIG. 5A is a plan view of a semiconductor device in accordance with an embodiment of the present invention. FIGS. 5B and 5C are cross-sectional views taken along a e I-I′ of FIG. 5A. FIG. 5D is a cross-sectional view taken along a line of FIG. 5A.

Referring to FIGS. 5A to 5D, a semiconductor device in accordance with an embodiment of the present invention includes a device isolation layer 33 disposed in a substrate 31 to define an active o region 34, a first trench 37 disposed on the substrate 31 to cross the active region 34 and the device isolation layer 33, a second trench 39 disposed in the substrate 31 under the first trench 37 to electrically isolate the active regions 34 which are adjacent to each other in the extending direction (i.e., the first direction) of the active region 34, and a gate electrode 41 disposed to fill the first and second trenches 37 and 39.

The active region 34 and the device isolation layer 33 may be line-type patterns that extend in the first direction. The active region 34 and the device isolation layer 33 may be formed using a line-type hard mask pattern 32A. If the hard mask pattern 32A is formed of a conductive layer, the hard mask pattern 32A isolated by the first trench 37 may serve as a landing plug.

The first trench 37 is to provide a space for forming a gate. The first trench 37 may be a line-type pattern that extends in the second direction that crosses the first direction at a predetermined angle. Referring to FIG. 5C, the first trench 37 may include a first pattern 35 disposed on the active region 34, and a second pattern 36 disposed on the device isolation layer 33. From the surface of the hard mask pattern 32A, the depth H2 of the second pattern 36 may be equal to or greater than the depth H1 of the first pattern 35 (H1=H2, or H1<H2). If the depth H2 of the second pattern 36 is greater than the depth H1 of the first pattern 35, the sidewalls of the active region 34 are exposed to a gate to be formed through subsequent processes to increase the channel width increases. Accordingly, the gate control power can be increased. Also, the first and second patterns 35 and 36 may have a cross section of a tetragon, a polygon or a bulb shape.

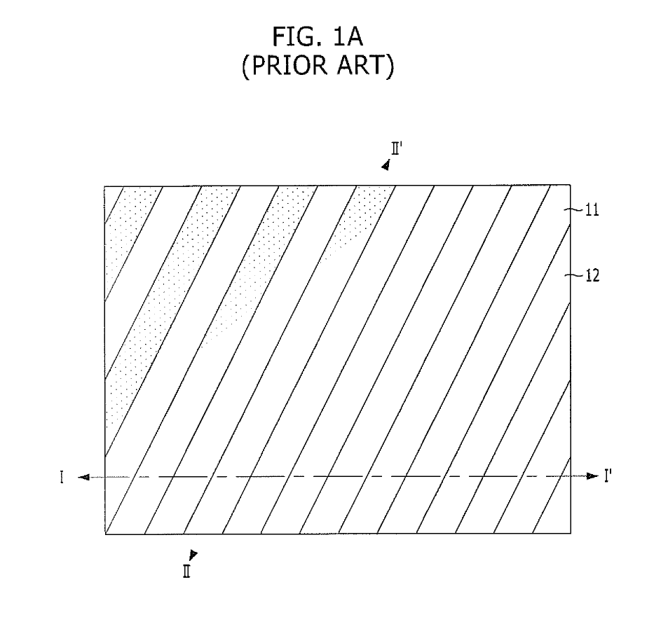

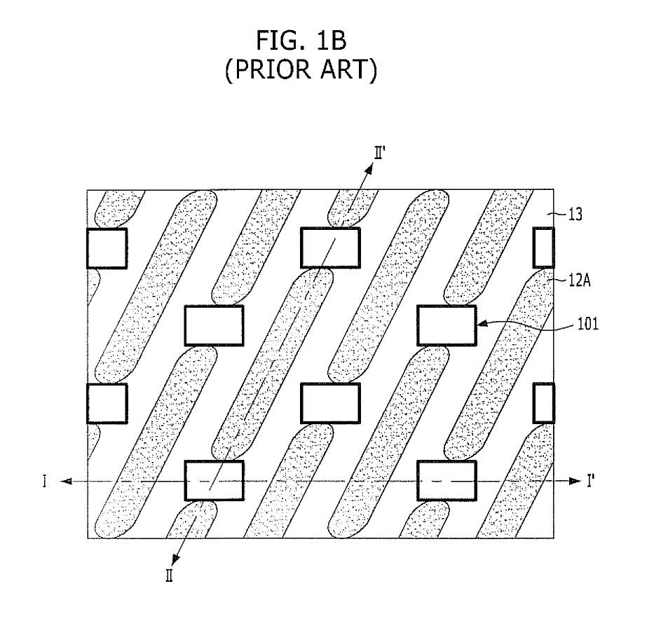

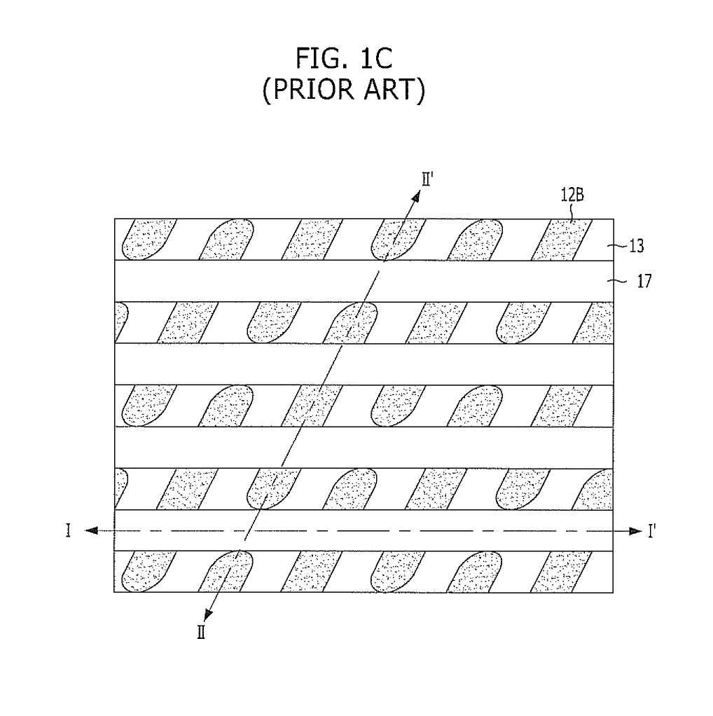

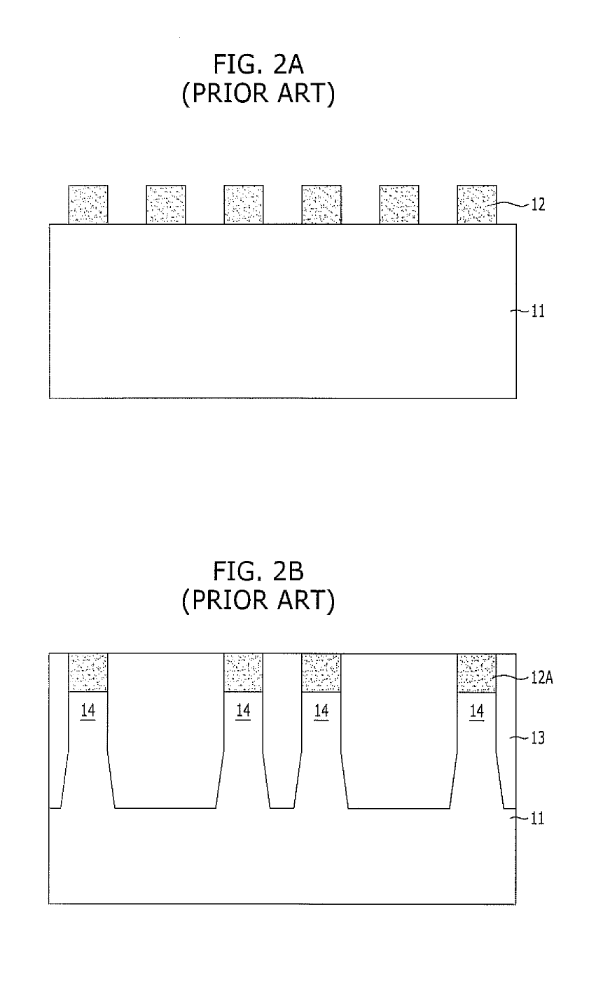

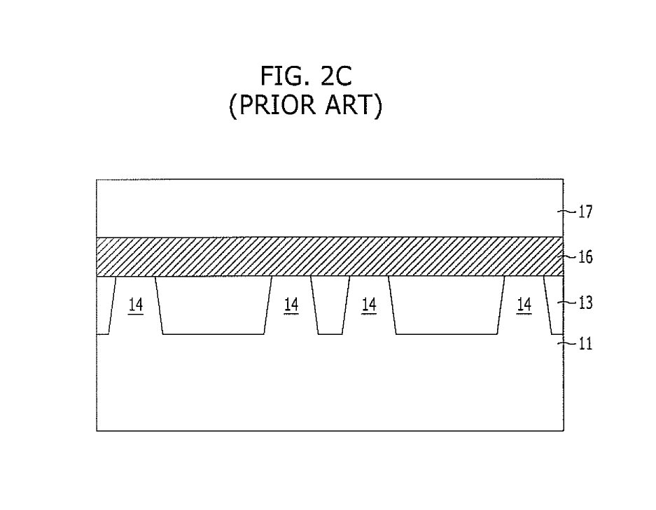

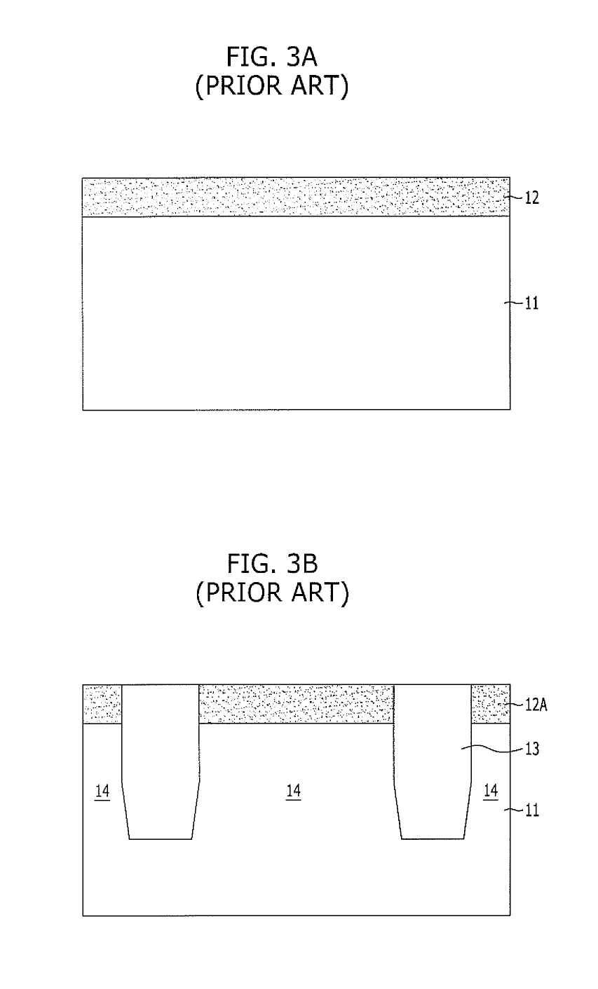

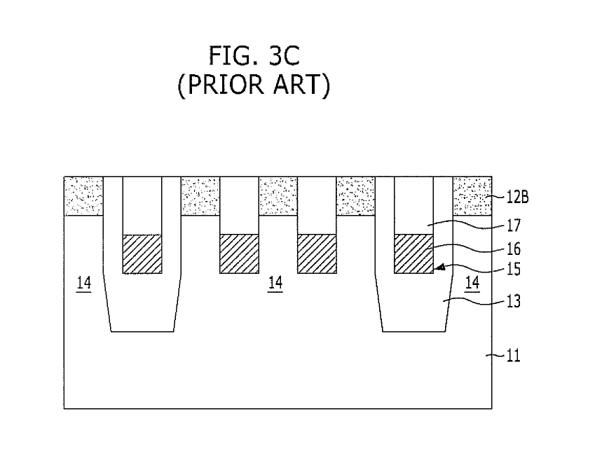

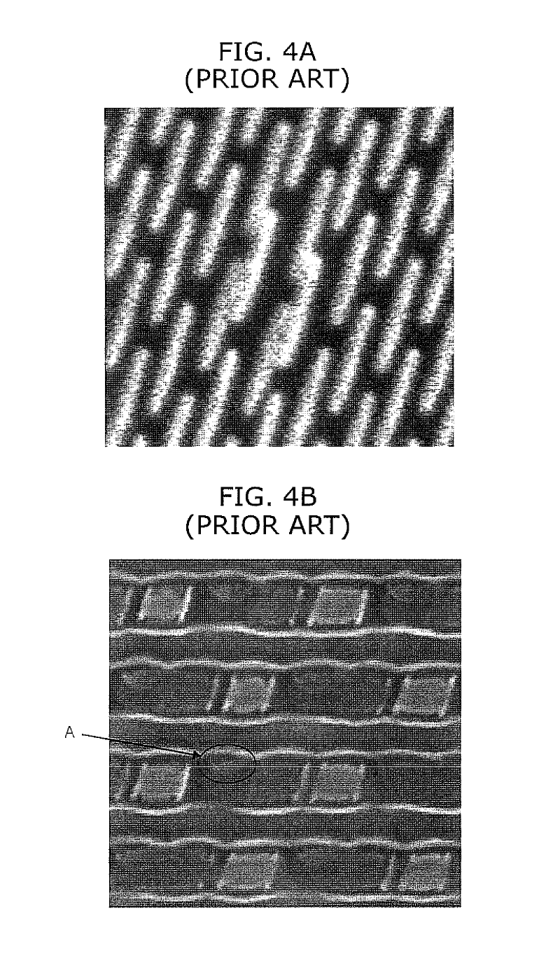

The second trench 39 disposed to electrically isolate the active regions 34 which are adjacent to each other in the first direction may be formed using an isolation cut mask (refer to ‘101’ of FIG. 1B). The second trench 39 may be disposed under the first trench 37 by further etching the first trench 37. In order to clearly isolate the adjacent active regions 34, the bottom of the second trench 39 may be lower than the bottom of the device isolation layer 33.

Also, the semiconductor device may further include a dopant region 40 that is disposed in the substrate 31 under the second trench 39 and includes a plurality of positive ions. Together with the second trench 39, the dopant region 40 serves to electrically isolate the adjacent active regions 34. The dopant region 40 may be formed by implanting dopants, which are capable of capturing mobile electrons, into the substrate 31. The dopants capable of capturing mobile electrons may include a material that has a smaller number of peripheral electrons than a material of the substrate 31. For example, if the substrate 31 is a silicon substrate, the dopant region 40 may include boron (B) or gallium (Ga).

As illustrated in the drawings, the gate electrode 41 may have the shape of a buried gate that fills the whole of the second trench 39 and fills a portion of the first trench 37. In this case, the semiconductor device may further include a sealing layer 42 that is disposed on the gate electrode 41 to fill the other portion of the first trench 37. Also, the gate electrode 41 may have the shape of a recess gate that fills the first and second trenches 37 and 39 and protrudes from the substrate 31. Although not illustrated in the drawings, a gate dielectric layer may be interposed between the substrate 31 and the gate electrode 41.

As described above, the semiconductor device in accordance with an embodiment of the present invention provides self-alignment isolation between the adjacent active regions 34 by disposing the second trench under the first trench that crosses the line-type active region and the device isolation layer, thereby preventing the alignment margin from being reduced in the gate forming process and the active region from being formed in a shorter length than a predetermined length in the extending direction of the active region. Also, the present invention may easily secure the contact margin between the active region and the storage node contact plug.

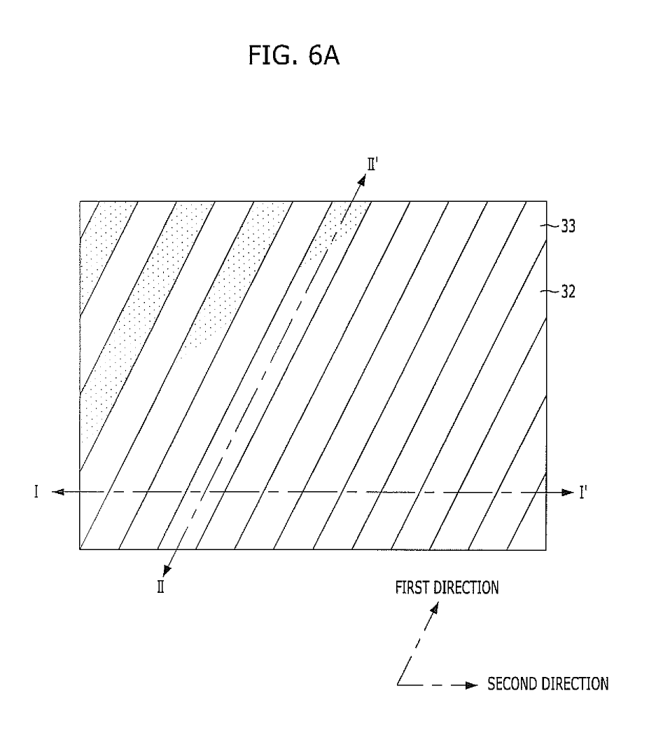

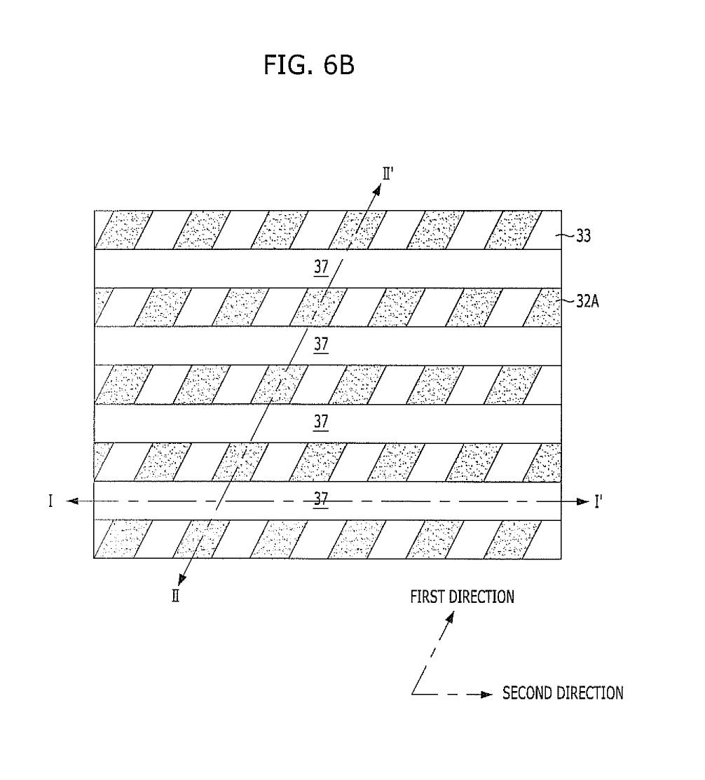

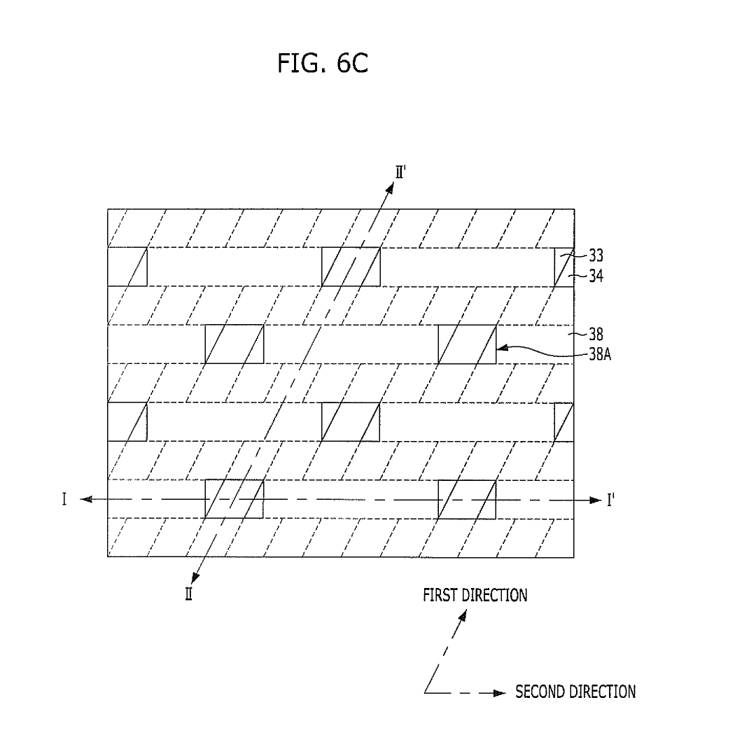

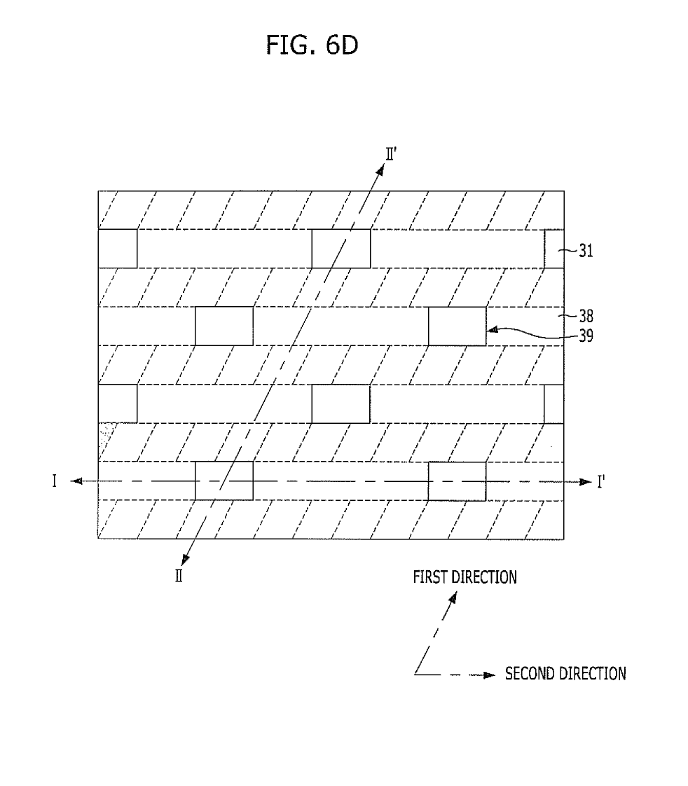

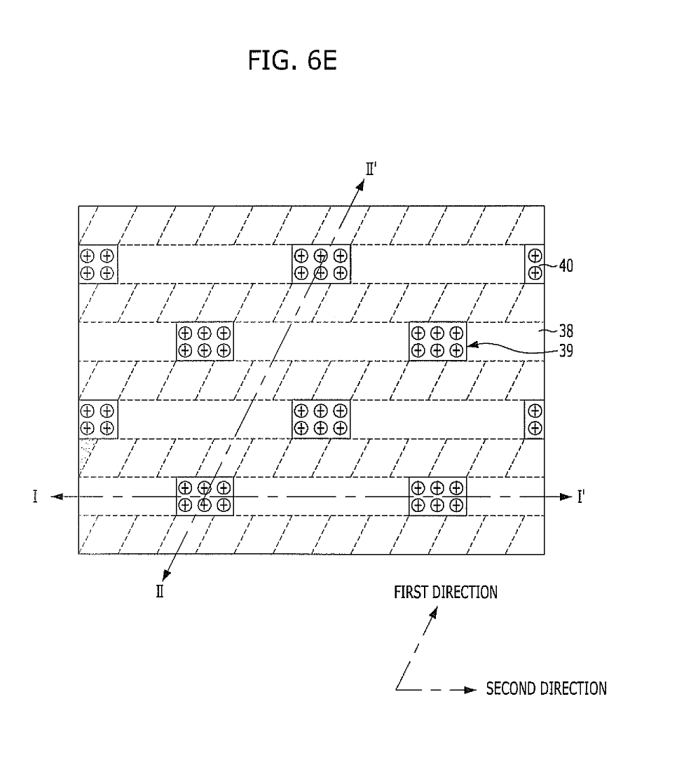

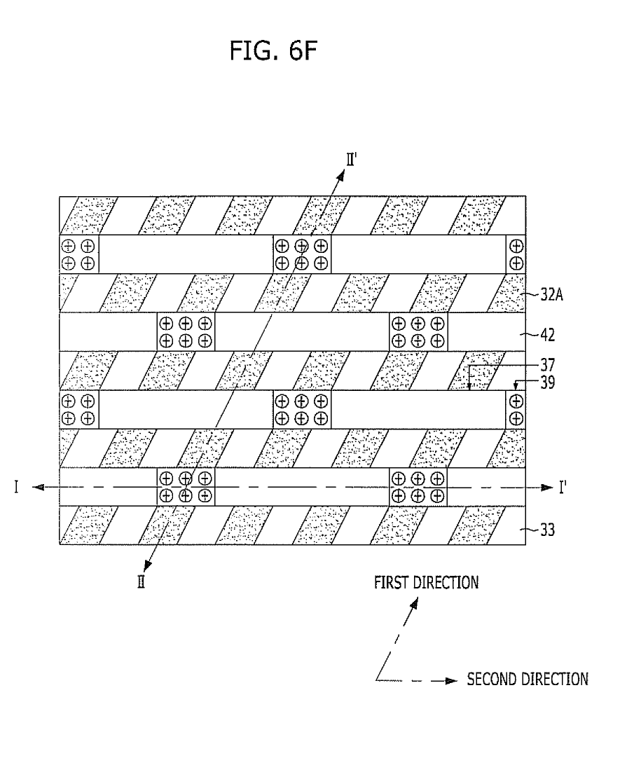

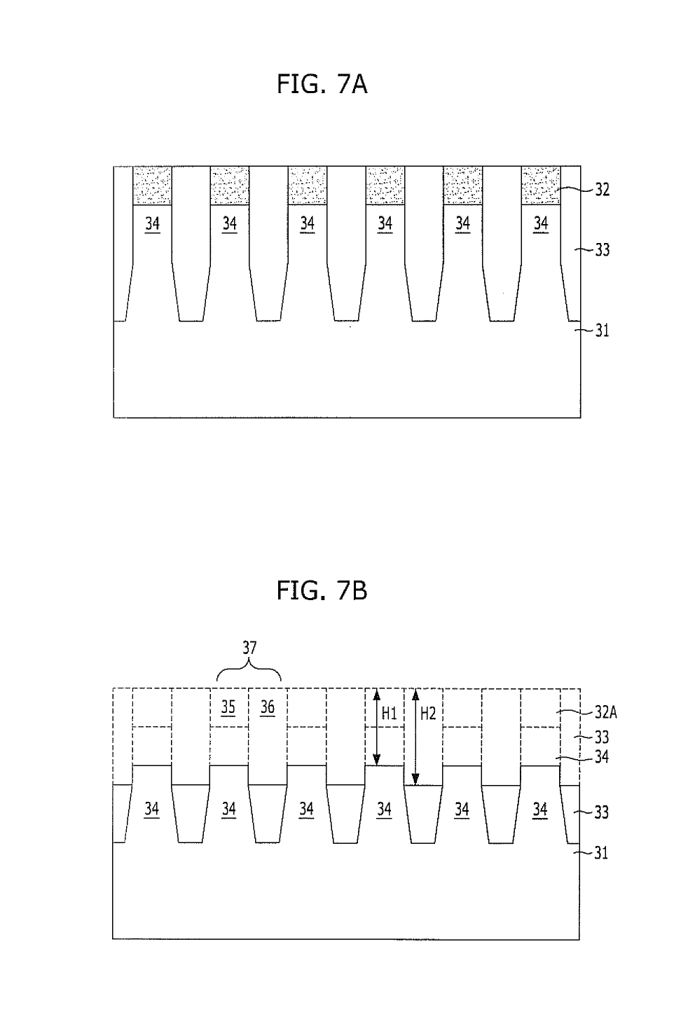

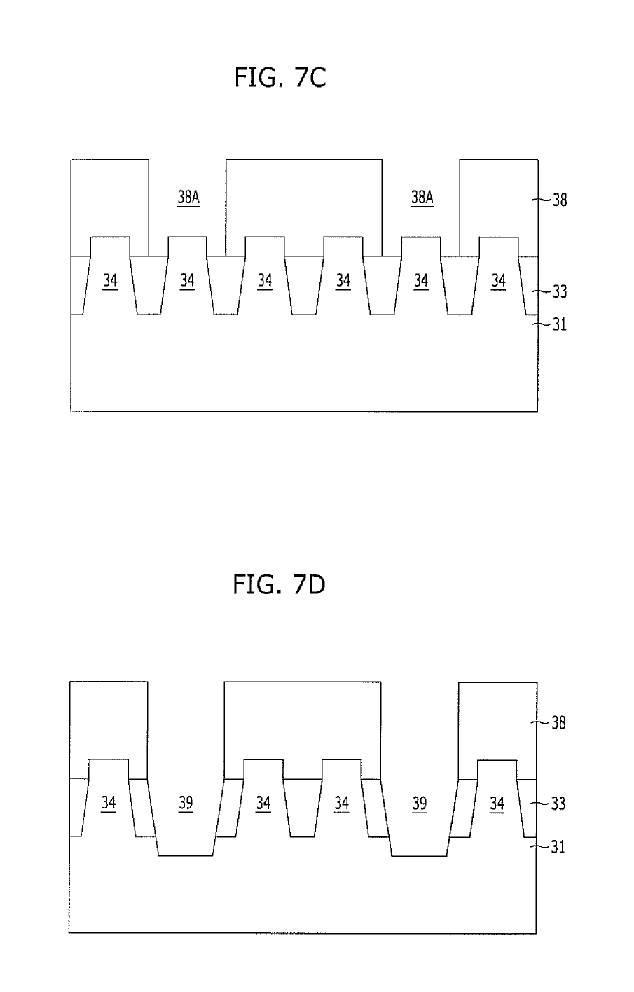

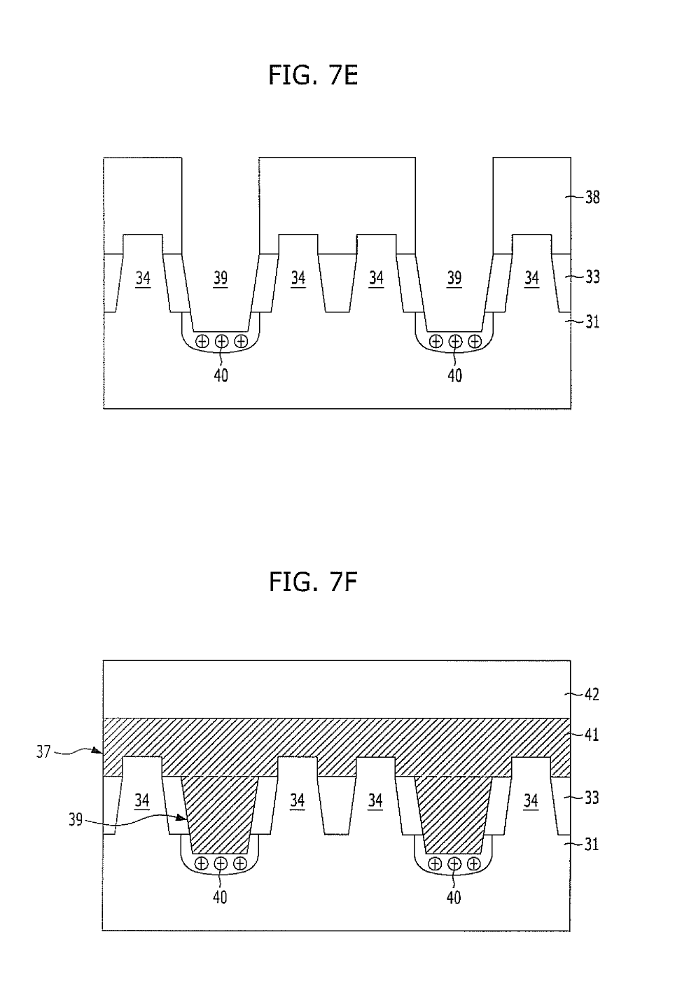

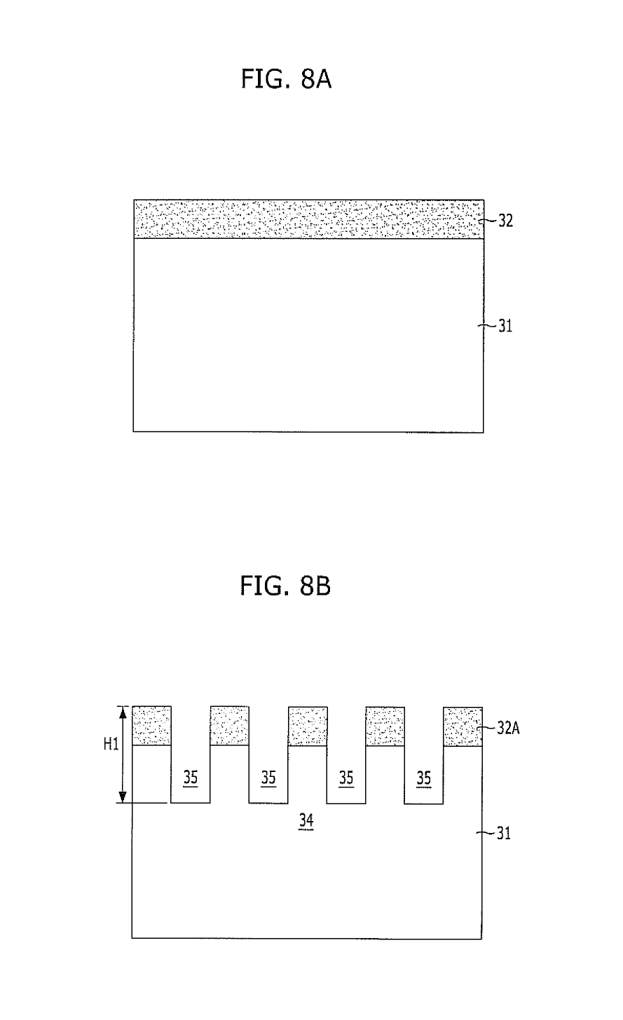

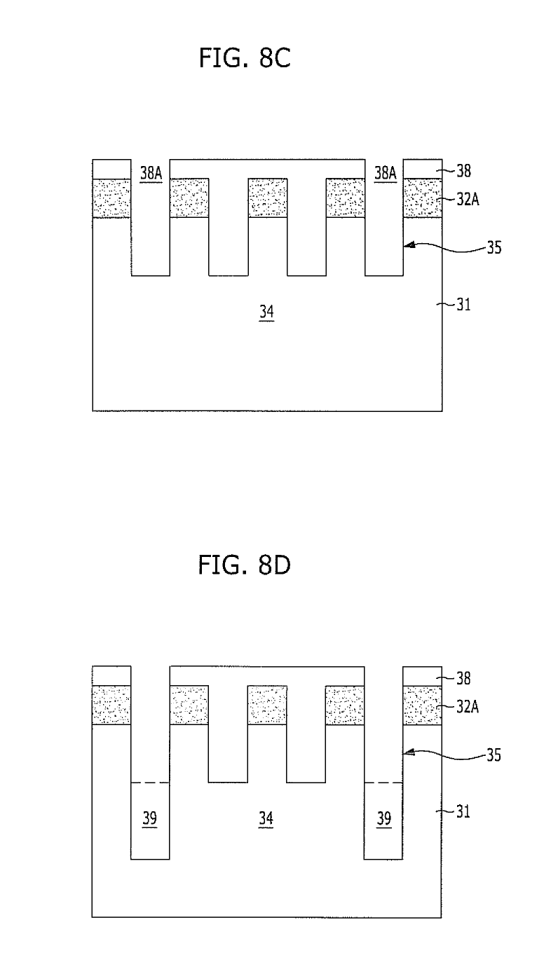

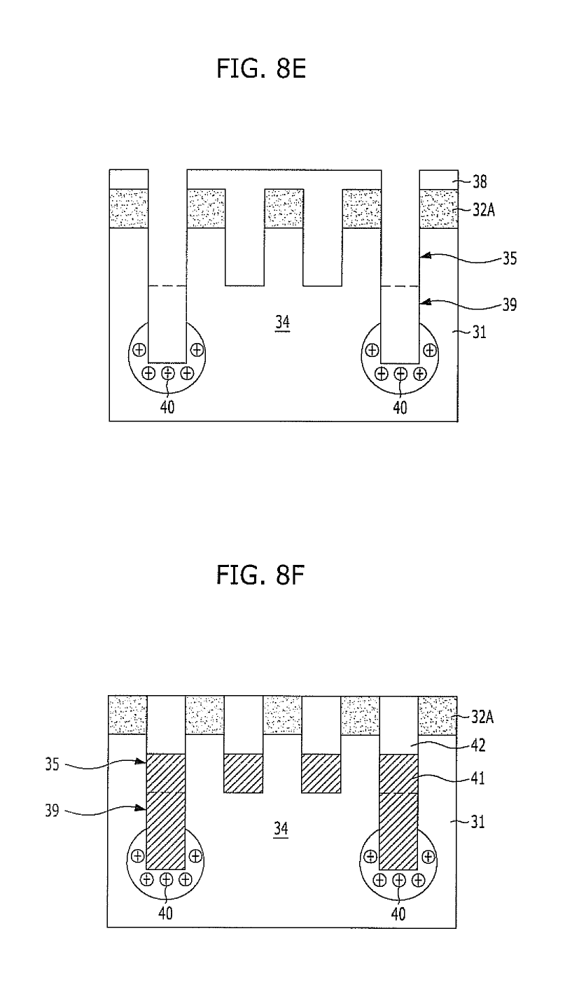

FIGS. 6A to 6F, FIGS. 7A to 7F, and FIGS. 8A to 8F are views illustrating a method for fabricating a semiconductor device in accordance with an embodiment of the present invention. FIGS. 6A to 6F are plan views illustrating a method for fabricating a semiconductor device in accordance with an embodiment of the present invention. FIGS. 7A to 7F are cross-sectional views taken along a line I-I′ of FIGS. 6A to 6F, respectively. FIGS. 8A to 8F are cross--sectional views taken along a line II-II′ of FIGS. 6A to 6F, respectively.

Referring to FIGS. 6A, 7A and 8A, a line-type hard mask pattern 32 extending in the first direction is formed on a substrate 31. The hard mask pattern 32 may be formed of a conductive layer or a dielectric layer. If the hard mask pattern 32 is formed of a conductive layer, the hard mask pattern 32 remaining after completion of a predetermined process may serve as a landing plug. In order to form the fine active region and the device isolation layer with the high integration of the semiconductor device, the line-type hard mask pattern 32 may be formed by double patterning technology (DPT) car spacer patterning technology (SPT).

Using the hard mask pattern 32 as an etch barrier, the substrate 31 is etched to form a trench for device isolation. The trench is filled with a dielectric layer, and a planarization process is performed until the hard mask pattern 32 is exposed, thereby forming a device isolation layer 33. The planarization process may be performed by chemical mechanical polishing (CMP).

An active region 34 is defined by the device isolation layer 33. The device isolation layer 33 and the active region 34 are formed in a line-type pattern because they are formed using the line-type hard mask pattern 32 extending in the first direction. That is, the hard mask pattern 32 can be prevented from leaning because the active region 34 and the device isolation layer 33 are formed by using the line-type hard mask pattern 32 instead of the conventional isolation cut mask.

Referring to FIGS. 6B, 7B and 8B, the hard mask pattern 32, the active region 34 and the device isolation layer 33 are selectively etched to form a line-type first trench 37 that extends in the second direction crossing the extending direction (i.e., the first direction) of the hard mask pattern 32. The first trench 37 serves to provide a space for forming a gate. Hereinafter, the hard mask pattern etched by forming the first trench 37 will be denoted by ‘32A’. If the hard mask pattern 32 is formed of a conductive layer, the hard mask pattern 32A remaining after the forming of the first trench 37 serves as a landing plug.

The first trench 37 may include a first pattern 35 formed on the active region 34, and a second pattern 36 formed on the device isolation layer 33. From the surface of the hard mask pattern 32A, the depth H2 of the second pattern 36 may be equal to or greater than the depth H1 of the first pattern 35 (H1=H2, or H1<H2). If the depth H2 of the second pattern 36 is greater than the depth H1 of the first pattern 35, the sidewalls of the active region 34 are exposed to a gate to be formed through subsequent processes to increase the channel width. Accordingly, the gate control power can be increased. Also, the first and second patterns 35 and 36 may have a cross section of a tetragon, a polygon or a bulb shape.

Referring to FIGS. 6C, 7C and 8C, a photoresist layer is formed to fill the first trench 37 and cover the substrate 31. An exposure and development process is performed to form a photoresist pattern 38 for isolating the active regions which are adjacent to each other in the first direction (or the major-axis direction). The photoresist pattern 38 may be formed using an isolation cut mask (refer to ‘101’ of FIG. 1B). Thus, an opening 38A of the photoresist pattern 38 is formed to expose the specific active region 34 in the trench 37 and the device isolation layer 33 located at both sides of the specific active region 34.

Referring to FIGS. 6D, 7D and 8D, using the photoresist pattern 38 as an etch barrier, the exposed active region 34 and the exposed device isolation layer 33 are etched to form a second trench 39 that is further etched from and is deeper than the first trench 37. In order to clearly isolate the active regions 34 which are adjacent to each other in the first direction, the second trench 39 may be formed to have a bottom lower than the bottom of the device isolation layer 33.

Referring to FIGS. 6E, 7E and 8E, using the photoresist pattern 38 as an ion implantation barrier, dopants capable of capturing mobile electrons are ion-implanted in the substrate 31 under the second trench 39 to form a dopant region 40. Together with the second trench 39, the dopant region 40 serves to effectively isolate the active regions 34 which are adjacent to each other in the first and second directions.

The dopants capable of capturing mobile electrons may include a material that has a smaller number of peripheral electrons than a material of the substrate 31. For example, if the substrate 31 is formed using silicon with four peripheral electrons, boron (B) or gallium (Ga) with three peripheral electrodes may be used as the dopants blocking the movement of electrons. Thus, the dopant region 40 includes a plurality of positive ions, and the positive ions of the dopant region 40 serve to capture mobile electrons moving between the adjacent active regions 34.

Referring to FIGS. 6F, 7F and 8F, the photoresist pattern 38 is removed, and a gate dielectric layer (not illustrated) is formed on the first and second trenches 37 and 39. A gate electrode 41 is formed to fill the first and second trenches 37 and 39. As illustrated in the drawings, the gate electrode 41 may be formed in the shape of a buried gate that fills the whole of the second trench 39 and fills a portion of the first trench 37. Also, although not illustrated in the drawings, the gate electrode 41 may be formed in the shape of a recess gate that fills the first and second trenches 37 and 39 and protrudes from the substrate 31.

A sealing layer 42 is formed over the substrate 31 to fill the other portion of the first trench 37, and a planarization process is performed until the hard mask pattern 32A is exposed. The sealing layer 42 may be formed of a dielectric layer, and the planarization process may be performed by chemical mechanical polishing (CMP).

In accordance with the embodiments of the present invention described above, the first trench for a gate is formed before isolating the active regions which are adjacent to each other in the first direction, thereby preventing the alignment margin from being reduced in the gate forming process and the active region from being formed in a shorter length than a predetermined length in the first direction. Also, the contact margin may be easily secured between the active region and the storage node contact plug (SNC) to be formed through the subsequent process.

As described above, the present invention forms the first trench for a gate before isolating the active regions which are adjacent to each other in the extending direction of the active regions, thereby preventing the alignment margin from being reduced in the gate forming process and the active region from being formed in a shorter length than a predetermined length in the extending direction of the active region. Also, the present invention may easily secure the contact margin between the active region and the storage node contact plug to be formed through the subsequent process.

While the present invention has been described with respect to the specific embodiments, it will be apparent to those skilled in the art that various changes and modifications may be made without departing from the spirit and scope of the invention as defined in the following claims.

What is claimed:

1. A semiconductor device comprising:
a device isolation layer disposed in a substrate to define active regions extending in a first direction;
a first trench disposed in the substrate to cross the active regions and the device isolation layer;
a second trench disposed under the first trench to isolate the active regions which are adjacent in the first direction; and
a gate electrode disposed in the first and second trenches.

2. The semiconductor device of claim 1, further comprising a dopant region that is disposed under the second trench and includes a plurality of positive ions.

3. The semiconductor device of claim 2, wherein the dopant region includes a material that has a smaller number of peripheral electrons than a material of the substrate.

4. The semiconductor device of claim 1, further comprising a landing plug that is disposed over the active region and is isolated by the first trench.

5. The semiconductor device of claim 1, wherein the active region and the device isolation layer are line-type patterns that extend an oblique direction.

6. The semiconductor device of claim 5, wherein the first trench is a line-type pattern that extends in a second direction crossing the active region and the device isolation layer.

7. The semiconductor device of claim 1, wherein a bottom of the second trench is lower than a bottom of the device isolation layer.

8. The semiconductor device of claim 1, wherein the first trench comprises:
a first pattern disposed over the active region; and
a second pattern disposed over the device isolation layer.

9. The semiconductor device of claim 8, wherein a depth of the second pattern is equal to or greater than a depth of the first pattern.

10. The semiconductor device of claim 8, wherein the first and second patterns have a cross section of a tetragon, a polygon or a bulb shape.

11. The semiconductor device of claim 1, wherein the gate electrode fills the whole of the second trench and fills a portion of the first trench.

12. The semiconductor device of claim 1, wherein the gate electrode fills the first and second trenches and protrudes from the substrate.

13. A method for fabricating a semiconductor device, comprising:
forming a device isolation layer defining active regions extending in a first direction in a substrate;
forming a first trench extending across the active regions and the device isolation layer by selectively etching the substrate;
forming a second trench under the first trench to isolate the active regions which are adjacent in the first direction by selectively etching the substrate; and
forming a gate electrode filling the first and second trenches.

14. The method of claim 13, further comprising, before the forming of the gate electrode, forming a dopant region including a plurality of positive ions in the substrate under the second trench.

15. The method of claim 14, wherein the dopant region is formed by ion-implanting dopants capturing mobile electrons in the substrate under the second trench.

16. The method of claim 15, wherein the dopants include a material that has a smaller number of peripheral electrons than a material of the substrate.

17. The method of claim 16, wherein the substrate includes silicon and the dopants include boron or gallium.

18. The method of claim 13, wherein the active region and the device isolation layer are formed in a shape of a line-type pattern that extends in an oblique direction.

19. The method of claim 18, wherein the forming of the device isolation layer defining the active regions in the substrate comprises:
forming a line-type hard mask pattern extending in the oblique direction over the substrate;
forming a third trench for the device isolation layer by etching the substrate by using the hard mask pattern as an etch barrier; and
filling the third trench with a dielectric material.

20. The method of claim 13, wherein the forming of the second trench comprises:
forming a photoresist pattern over the substrate by using an isolation cut mask; and
etching the substrate by using the photoresist pattern as an etch barrier.

21. The method of claim 13, wherein the forming of the first trench comprises:
forming a first pattern over the active region; and
forming a second pattern over the device isolation layer.
